(19) United States
(12) Patent Application Publication
(10) Pub. No.: US 2007/0108467 A1
(43) Pub. Date: May 17, 2007

(54) Vertical GaN-based light emitting diode

(75) Inventors: Tae Sung Jang, Suwon (KR); Su Yeol Lee, Seongnam (KR); Pil Geun Kang, Suwon (KR); Tae Jun Kim, Pyeongtaek (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/599,266

(22) Filed: Nov. 15, 2006

(30) Foreign Application Priority Data
Nov. 15, 2005 (KR) 10-2005-0108872

(51) Int. Cl. H01L 33/00

(52) U.S. Cl. 257/103

(57) ABSTRACT

A vertical GaN-based LED is provided. The vertical GaN-based LED includes an n-type bonding pad, an n-type reflective electrode formed under the n-type bonding pad, an n-type transparent electrode formed under the n-type reflective electrode, an n-type GaN layer formed under the n-type transparent electrode, an active layer formed under the n-type GaN layer, a p-type GaN layer formed under the active layer, a p-electrode formed under the p-type GaN layer and having an uneven profile at a surface which does not come in contact with the p-type GaN layer, a p-type reflective electrode formed along the uneven surface of the p-type electrode, and a support layer formed under the p-type reflective electrode.

### CROSS-REFERENCE TO RELATED APPLICATIONS

This application claims the benefit of Korean Patent Application No. 2005-108872 filed with the Korean Industrial Property Office on Nov. 15, 2005, the disclosure of which is incorporated herein by reference.

### BACKGROUND OF THE INVENTION

1. Field of the Invention

The present invention relates to a vertical (vertical electrode type) gallium nitride (GaN)-based light emitting diode (LED) and a method of manufacturing the same. The vertical GaN-based LED can increase the light extraction efficiency, thereby improving the external quantum efficiency.

2. Description of the Related Art

Generally, GaN-based LEDs are grown on a sapphire substrate. The sapphire substrate is a rigid nonconductor and has a low thermal conductivity. Therefore, it is difficult to reduce the size of the GaN-based LED for cost-down or improve the optical power and chip characteristics. Particularly, heat dissipation is very important for the LEDs because a high current should be applied to the GaN-based LEDs so as to increase the optical power of the GaN-based LEDs. To solve these problems, a vertical GaN-based LED has been proposed. In the vertical GaN-based LED, the sapphire substrate is removed using a laser lift-off (hereinafter, referred to as LLO) technology.

The vertical GaN-based LED according to the related art will be described below with reference to FIG. 1.

Referring to FIG. 1, the conventional vertical GaN-based LED includes an n-type bonding pad 110, an n-type reflective electrode 120, an n-type transparent electrode 130, an n-type GaN layer 140, an active layer 150, a p-type GaN layer 160, a positive electrode (p-electrode ) 170, and a support layer 190, which are sequentially formed under the n-type bonding pad 110. The n-type transparent electrode 130 is used for improving the current diffusion efficiency.

In FIG. 1, a reference numeral 180 represents a plating seed layer used as a plating crystal nucleus when the support layer 190 is formed by electroplating or electroless plating.

In the conventional vertical GaN-based LED, however, because the p-electrode formed under the p-type GaN layer is formed of Cr/Au, it absorbs or totally reflects some of light emitted from the active layer. Thus, an entire luminous efficiency of the LED is degraded.

### SUMMARY OF THE INVENTION

An advantage of the present invention is that it provides a vertical GaN-based LED in which a p-electrode is formed of a transparent layer with an uneven surface so that the external quantum efficiency is maximized and a current spreading effect is improved so as to secure a high power characteristic.

Additional aspect and advantages of the present general inventive concept will be set forth in the description which follows and, in part, will be obvious from the description, or may be learned by practice of the general inventive concept.

According to an aspect of the invention, a vertical GaN-based LED includes: an n-type bonding pad; an n-type reflective electrode formed under the n-type bonding pad; an n-type transparent electrode formed under the n-type reflective electrode; an n-type GaN layer formed under the n-type transparent electrode; an active layer formed under the n-type GaN layer; a p-type GaN layer formed under the active layer; a p-electrode formed under the p-type GaN layer, the p-electrode having an uneven profile at a surface which does not come in contact with the p-type GaN layer; a p-type reflective electrode formed along the uneven surface of the p-type electrode; and a support layer formed under the p-type reflective electrode.

According to another aspect of the present invention, the p-type electrode is formed of a transparent layer, more preferably, TCO or Ni/Au. The TCO is a mixture made by adding at least one element selected from the group consisting of Sn, Zn, Ag, Mg, Cu, and Al to indium oxide.

According to a further aspect of the present invention, the vertical GaN-based LED further includes an adhesive layer formed at an interface between the p-type GaN layer and the p-electrode.

According to a still further aspect of the present invention, the adhesive layer is a transparent layer and is formed of a material different from that of the p-electrode.

According to a still further aspect of the present invention, the adhesive layer is formed of a mixture made by adding at least one element selected from a group consisting of Sn, Zn, Ag, Mg, Cu, and Al to indium oxide, and the element added to the adhesive layer is different from the element added to the TCO. Moreover, it is preferable that an amount of the element added to the adhesive layer is different from an amount of the element added to the TCO forming the p-electrode.

According to a still further aspect of the present invention, it is preferable that the adhesive layer has a thickness of 1˜200 Å because its transmissivity decreases as its thickness increases.

According to a still further aspect of the present invention, the p-type reflective electrode has the uneven profile at the surface that does not contact the support layer, and thus the support layer is formed using a plating seed by electroplating or electroless plating.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view of a vertical GaN-based LED according to the related art; and

FIG. 2 is a sectional view of a vertical GaN-based LED according to the present invention.

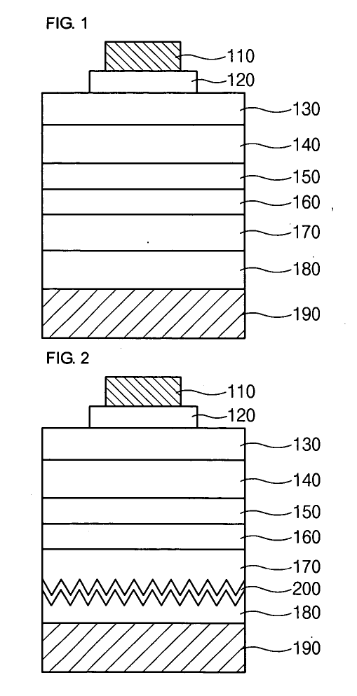

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a vertical GaN-based LED according to the present invention will be described in detail with reference to FIG. 2.

FIG. 2 is a sectional view of a vertical GaN-based LED according to the present invention.

Referring to FIG. 2, an n-type bonding pad 110 for electrical connection to an external device is formed at the uppermost portion of the vertical GaN-based LED.

An n-type reflective electrode 120 for improving the luminous efficiency is formed under the n-type bonding pad 110.

An n-type GaN layer 140 is formed under the n-type reflective electrode 120. More specifically, the n-type GaN layer 140 may be formed of an n-doped GaN layer or an n-doped GaN/AlGaN layer.

In order to improve the current spreading effect, an n-type transparent electrode 130 is further formed at the interface between the n-type reflective electrode 120 and the n-type GaN layer 140.

An active layer 150 and a p-type GaN layer 160 are sequentially formed under the n-type GaN layer 140, thereby forming a GaN-based LED structure.

In the GaN-based LED structure, the active layer 150 may be formed in a multi-quantum well structure with InGaN/GaN layer. Like the n-type GaN layer 140, the p-type GaN layer 160 may be formed of a p-doped GaN layer or a p-doped GaN/AlGaN layer.

A p-electrode 170 is formed under the p-type GaN layer 160 of the GaN-based LED structure. The p-electrode 170 is preferably formed of a transparent layer, more preferably, transparent conductive oxide (TCO) or Ni/Au. The TCO is a mixture made by adding at least one element selected from the group consisting of Sn, Zn, Ag, Mg, Cu, and Al to indium oxide.

Unlike the conventional p-electrode formed of Cr/Au, the p-electrode 170 according to the present invention is formed of a transparent layer such as TCO or Ni/Au. Therefore, an amount of light emitted from the active layer and absorbed by the p-type electrode is minimized, thereby improving both the luminous efficiency and the current spreading effect.

Further, the bottom surface of the p-electrode 170, which does not come in contact with the p-type GaN layer 160, has an uneven profile. Therefore, the light emitted from the active layer is scattered by the uneven surface, thereby maximizing the external quantum efficiency.

Although not shown, an adhesive layer may be further formed at an interface between the p-electrode 170 and the p-type GaN layer 160 so as to increase their adhesive strength. As the thickness of the adhesive layer increases, its transmittance decreases. Therefore, it is preferable that the adhesive layer has a thickness of 1˜200 Å.

The adhesive layer is formed of a transparent layer. However, it is preferable that the adhesive layer is formed of a material different from that of the p-electrode 170. More specifically, in order to obtain the excellent adhesive strength, the adhesive layer is formed of a mixture made by adding at least one element selected from the group consisting of Sn, Zn, Ag, Mg, Cu, and Al to indium oxide. It is preferable that the element added to the adhesive layer is different from the element added to the TCO, or an amount of the element added to the adhesive layer is different from an amount of the element added to the TCO.

A p-type reflective electrode 200 is formed along the uneven surface of the p-electrode 170. Therefore, the p-type reflective electrode 200 also has the uneven profile, so that the light emitted from the active layer 150 can be prevented from being totally reflected and lost.

Under the p-type reflective electrode 200, a support layer 190 is formed of a plating layer. The plating slayer is formed using a plating seed layer 180 by electroplating or electroless plating.

Although the support layer 190 is provided with the plating layer formed by using the plating seed layer 180 as a crystal nucleus, the present embodiment is not limited thereto. That is, the support layer may be formed of a Si substrate, a GaAs substrate, a Ge substrate, or a metal layer, which can serve as a support layer of a final LED and an electrode.

In addition, the metal layer may be formed using thermal evaporator, e-beam evaporator, sputter, and chemical vapor deposition (CVD).

As described above, the p-electrode is formed to have the uneven surface, so that the light emitted from the active layer can be prevented from being absorbed or scattered by the p-electrode. Then, it is possible to improve the light extraction efficiency and maximizing the external quantum efficiency.

Furthermore, the current spreading effect is improved by forming the p-electrode of the transparent layer, thereby obtaining the high power characteristic.

Consequently, the present invention can improve the characteristics and reliability of the vertical GaN-based LED.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A vertical gallium nitride (GaN)-based light emitting diode (LED) comprising:
an n-type bonding pad;
an n-type reflective electrode formed under the n-type bonding pad;
an n-type transparent electrode formed under the n-type reflective electrode;
an n-type GaN layer formed under the n-type transparent electrode;
an active layer formed under the n-type GaN layer;
a p-type GaN layer formed under the active layer;
a p-electrode formed under the p-type GaN layer, the p-electrode having an uneven profile at a surface which does not come in contact with the p-type GaN layer;
a p-type reflective electrode formed along the uneven surface of the p-type electrode; and
a support layer formed under the p-type reflective electrode.

2. The vertical GaN-based LED according to claim 1,
wherein the p-type electrode is formed of a transparent layer.

3. The vertical GaN-based LED according to claim 2,
wherein the transparent layer is formed of TCO or Ni/Au.

4. The vertical GaN-based LED according to claim 3,
wherein the TCO is a mixture made by adding at least one element selected from a group consisting of Sn, Zn, Ag, Mg, Cu, and Al to indium oxide.

5. The vertical GaN-based LED according to claim 1, further comprising
an adhesive layer formed at an interface between the p-type GaN layer and the p-electrode.

6. The vertical GaN-based LED according to claim 5,
wherein the adhesive layer is a transparent layer and is formed of a material different from that of the p-electrode.

7. The vertical GaN-based LED according to claim 6,
wherein the adhesive layer is formed of a mixture made by adding at least one element selected from a group consisting of Sn, Zn, Ag, Mg, Cu, and Al to indium oxide, the element added to the adhesive layer being different from the element added to the TCO forming the p-electrode.

8. The vertical GaN-based LED according to claim 6,
wherein the adhesive layer is formed of a mixture made by adding at least one element selected from a group consisting of Sn, Zn, Ag, Mg, Cu, and Al to indium oxide, an amount of the element added to the adhesive layer being different from an amount of the element added to the TCO forming the p-electrode.

9. The vertical GaN-based LED according to claim 5,
wherein the adhesive layer has a thickness of 1-200 Å.

10. The vertical GaN-based LED according to claim 1,
wherein the support layer is formed using a plating seed by electroplating or electroless plating.
